(19) United States
(12) Patent Application Publication
(10) Pub. No.: US 2010/0321036 A1
(43) Pub. Date: Dec. 23, 2010

(54) DUAL TONE MEASUREMENT OF CONDUCTIVITY AND DIELECTRIC PROPERTIES

(75) Inventor: Robert W. Camp, Carlisle, PA (US)

Correspondence Address: Vern Maine & Associates, 547 AMHERST STREET, 3RD FLOOR, NASHUA, NH, 03063-4000, US

(73) Assignee: DELAWARE CAPITAL FORMATION, INC., Wilmington, DE (US)

(21) Appl. No.: 12/819,419

(22) Filed: Jun. 21, 2010

Related U.S. Application Data
(60) Provisional application No. 61/219,010, filed on Jun. 22, 2009.

(51) Int. Cl. G01R 27/28

(52) U.S. Cl. 324/649; 324/140 R

(57) ABSTRACT

The invention relates to a method of simultaneously determining both the conductivity and dielectric properties of a sample such as lubricating oil or a fuel. First and second signals are applied to a test cell through a combiner. Output of the cell is measured by a pair of frequency selective AC voltage measuring devices through a load on the output of the test cell. Through simultaneous readings, conductivity and dielectric properties are accurately calculated rather than estimated.

### RELATED APPLICATIONS

This application claims the benefit of U.S. Provisional Application No. 61/219,010 filed Jun. 22, 2009. This application is herein incorporated by reference in its entirety for all purposes.

### FIELD OF THE INVENTION

The invention relates to measuring electrical properties of samples. More specifically, devices and methods for simultaneously determining both the conductivity and dielectric properties of a material such as lubricating oil or fuels.

### BACKGROUND OF THE INVENTION

Previous approaches to measuring conductivity and dielectric properties include frequency sweeping, measuring magnitude only (no cross calculation), and single frequency testing.

In measurements of sample properties, parameters are interrelated. Such electrical parameters include susceptance, which is the imaginary part of the admittance, which is a measure of how easily a circuit or device will allow a current to flow, and electrical conductance, which is a measure of how easily electricity flows along a certain path through an electrical element. A need exists for accurate simultaneous measurement of multiple parameters for a given sample.

### SUMMARY OF THE INVENTION

Embodiments of the present invention allow the conductivity and dielectric of a sample to be continuously monitored. They allow a wide range of samples to be estimated with a single setup. The parameter value range is established by the ability to space the two applied signal sources far apart in frequency. Because the signals are continuous, in embodiments, the technique reduces noise through long integration times. Without switching, data may be provided more quickly than with a start/stop approach. By using two simultaneous readings, the conductivity and dielectric properties can be accurately calculated rather than simply estimated. By employing fixed frequencies, the calibration and maintenance of the test apparatus is simplified.

An exemplary embodiment is an apparatus for measuring conductivity and dielectric properties of a sample, the apparatus comprising a test cell for the sample; at least a first sine wave signal source producing at least a first signal; at least a second sine wave signal source producing at least a second signal; a combiner combining the at least a first signal and the at least a second signal; electrodes applying the at least a first signal and the at least a second signal to the test cell; a load on an output of the test cell; at least one measuring device, measuring output of the load; and a processor calculating conductivity and dielectric of the sample as a function of voltages measured by the at least one measuring device. In another embodiment, the at least one measuring device comprises at least a pair of frequency selective AC voltage measuring devices. For other embodiments, the at least one measuring device comprises shared frequency selective AC voltage measuring components. Other embodiments provide that the at least one measuring device comprises at least one root mean square (RMS) detector. For further embodiments, the at least a first signal is a fixed frequency signal and the at least a second signal is a fixed frequency signal. In yet further embodiments, the at least a first signal and the at least a second signal are continuous, thereby reducing noise through long integration times. For yet other embodiments, varying the amplitude of at least one of the at least a first signal and the at least a second signal is accomplished at the combiner. For more embodiments, varying amplitude of at least one of the at least a first signal and the at least a second signal is accomplished at least one of the at least a first sine wave signal source and the at least a second sine wave signal source; and the test cell comprises at least a second set of connections, whereby samples having at least one of a very high dielectric or a very high conductivity are measured. In some additional embodiments the load is an operational amplifier (op amp) acting as a transimpedance amplifier; and the load is an operational amplifier with a feedback network. For further embodiments, the feedback network is a feedback resistor wherein gain of the test cell plus the feedback resistor equals feedback resistance divided by impedance of the test cell; and the feedback network comprises a feedback resistor and a capacitor in parallel with the feedback resistor wherein gain at high and low signal frequencies is equalized. Another embodiment provides that feedback capacitance equals the highest anticipated value of the dielectric (∈ᵣ) multiplied by the cell constant of the test cell, and the resistance value of the feedback resistor equals the inverse of the highest anticipated value of the conductivity multiplied by the cell constant of the test cell.

Another exemplary embodiment is a method for measuring conductivity and dielectric properties of at least one sample, the method comprising estimating a corner frequency of the sample; selecting at least a first sine wave source frequency below the corner frequency; selecting at least a second sine wave source frequency above the corner frequency; applying at least a first sine wave signal at the at least a first sine wave source frequency to a summer; applying at least a second sine wave signal at the at least a second sine wave source frequency to the summer; applying output of the summer to a test cell of the sample; measuring the output of a load of the test cell with at least one AC voltage measurement component; tuning the at least one AC voltage measuring component to the at least a first source frequency, producing at least a first measurement; tuning the at least one AC voltage measuring component to the at least a second source frequency, producing at least a second measurement; processing the at least a first measurement and the at least a second measurement; providing values of conductivity and dielectric properties of the sample from the processing. In a subsequent embodiment, the step of estimating a corner frequency of the sample comprises estimating the corner frequency to be where the susceptance equals the conductance of the sample, and wherein the range of values of the conductivity and the dielectric of the sample is determined in advance. In one additional embodiment, the amplitude of at least one of the at least a first sine wave signal and the at least a second sine wave signal is varied, thereby extending the dynamic range. Other embodiments include the step of adjusting the value of at least one resistor of the summer to provide equal levels of signals at the output of the test cell. For another further embodiment, the at least one sample comprises multiple samples; wherein the at least a first sign wave source frequency is below the lowest corner frequency of the multiple samples and the at least a second sign wave source frequency is above the highest corner frequency of the multiple samples.

Yet another exemplary embodiment is an apparatus for measuring conductivity and dielectric properties of a sample, the apparatus comprising a test cell for the sample, the sample comprising at least one of oil, fuels, and gasoline/ethanol mixtures, wherein the test cell is a multi-element test cell comprising four wires, whereby accuracy is enhanced; at least a first sine wave signal source producing at least a first signal; at least a second sine wave signal source producing at least a second signal, wherein the property parameter value range is established by an ability to space the at least a first signal and the at least a second signal far apart in frequency; a combiner combining the at least a first signal and the at least a second signal, wherein the combiner comprises a resistive summer producing a combined signal, and wherein the combiner comprises a low pass filter whereby noise is limited; electrodes applying the at least a first signal and the at least a second signal to the test cell; a load on an output of the test cell, wherein the load is a resistor; at least a pair of frequency selective AC voltage measuring devices measuring output of the load; and a processor calculating values of the conductivity and the dielectric properties of the sample as a function of voltages measured by the at least a pair of frequency selective AC voltage measuring devices, whereby simultaneous readings of the conductivity and the dielectric properties are accurately calculated rather than estimated.

Embodiments include a system for measuring properties of a sample comprising a test cell for the sample; at least a first and a second sine wave signal source having fixed frequencies; a combiner of the sources, such as a resistive summer producing a combined signal; electrodes to apply the combined signal to the test cell; a load on an output of the test cell, such as a resistor; at least a pair of frequency selective AC voltage measuring devices for measuring output of the load; and a processor to calculate conductivity and dielectric of the sample as a function of voltages measured by the AC voltage measuring devices.

Other embodiments provide a method for measuring properties of a sample comprising estimating a corner frequency where susceptance equals conductance of the sample; selecting at least a first sine wave source frequency below the corner frequency, for multiple samples the at least a first source frequency is set below the lowest corner frequency of the multiple samples; selecting at least a second sine wave source frequency above the corner frequency, for multiple samples the at least a second source frequency is set above the highest corner frequency of the multiple samples; applying the at least a first sine wave source and the at least a second source to a summer; applying output of the summer to a test cell of the sample; applying a load to the test cell for measurement of output signal from the test cell; measuring output of the load with at least a first and at least a second AC voltage measurement component; tuning the at least a first voltage measuring component to the at least first source; tuning the at least a second voltage measuring component to the at least second source; processing measurements of the at least a first voltage measuring component and at least a second voltage measuring component; providing values of conductivity and dielectric properties of the sample.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a simplified diagram of a measurement system configured in accordance with an embodiment.

FIG. 2 is a simplified circuit diagram in accordance with one embodiment.

FIG. 3 is a first flow chart of a method in accordance with one embodiment.

FIG. 4 is a second flow chart of a method in accordance with one embodiment.

### DETAILED DESCRIPTION

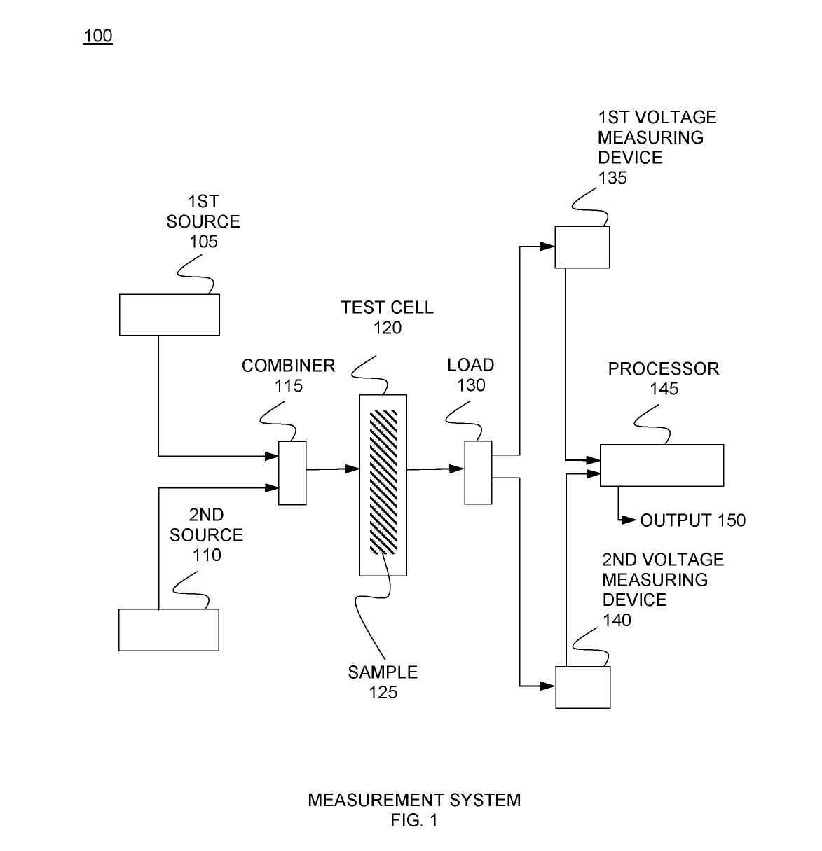

FIG. 1 is a simplified diagram 100 of an embodiment of a measurement system. The setup comprises a pair of sine wave signal sources 105 and 110 having fixed frequencies; a method of combining these sources 115, such as a resistive summer; test cell 120 containing sample 125; load 130, such as a resistor, on test cell 120; a pair of frequency selective AC voltage measuring devices 135 and 140; and a processor 145 to calculate the conductivity and dielectric as a function of the voltages observed; with output 150. In embodiments, test cell electrodes have a second set of connections or multiple elements for sample materials with a very high dielectric or a very high conductivity. For some embodiments, the summer includes a low pass filter to limit noise. Furthermore, the load in some embodiments is an op amp acting as a transimpedance (current to voltage) amplifier. The voltage measuring devices are root mean square (RMS) detectors in certain embodiments. Material samples 125 for measurement can contain fluids such as oil, or fuels, e.g. gasoline/ethanol mixtures.

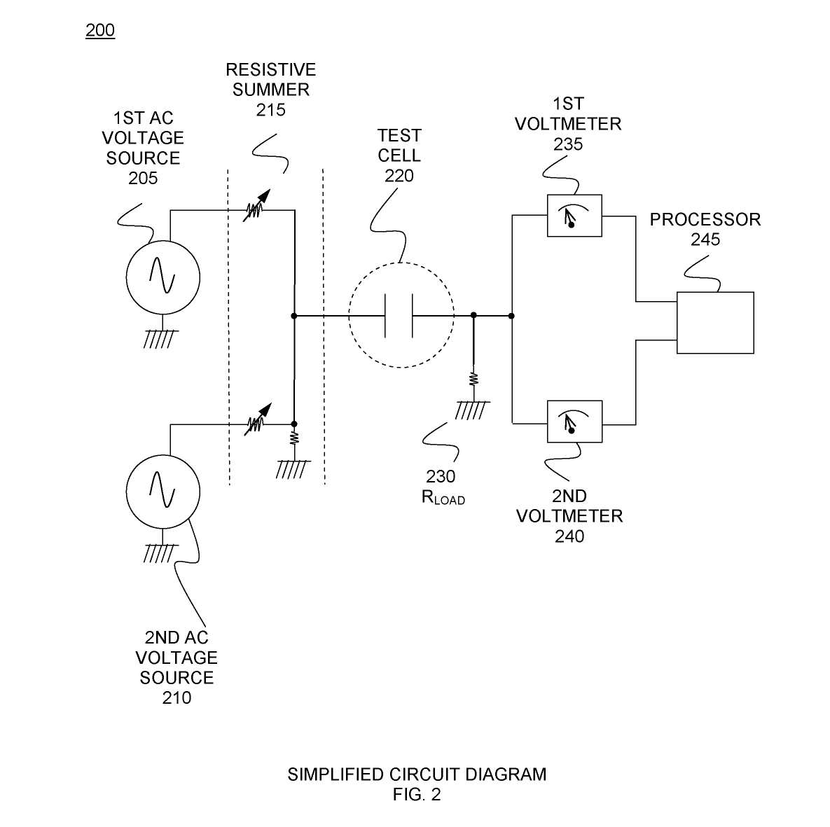

FIG. 2 is a simplified circuit diagram 200 of an embodiment of a measurement system. AC voltage sources 205 and 210 send signals to test cell 220 through resistive summer 215. Resistive load 230 is between test cell 220 and voltmeters 235 and 240. Processor 245 receives output of voltmeters 235 and 240. For embodiments, the summer resistors are adjusted to provide equal tone levels at the output of the cell (cell load).

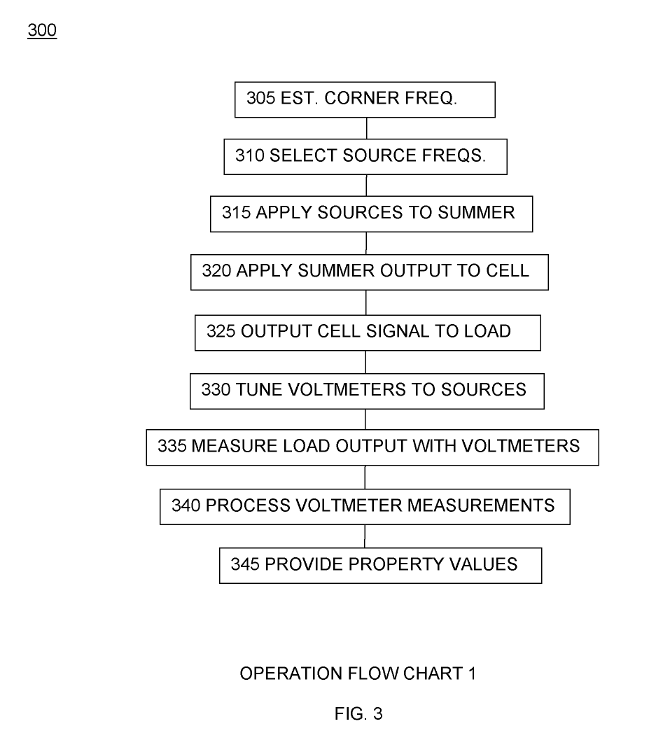

FIG. 3 is a first flow chart 300 of a method of operation of an embodiment of the invention. The method comprises estimating a corner frequency where susceptance equals conductance of sample 305; selecting sine wave source frequencies above and below the corner frequency 310; applying the sources to a summer 315; applying output of summer to a test cell of sample 320; applying test cell output signal to a load 325; tuning voltmeters to sources 330; measuring output of said load with voltmeters 335; processing voltmeter measurements 340; providing values of conductivity and dielectric properties of sample 345. The order of steps provided may be varied in some embodiments.

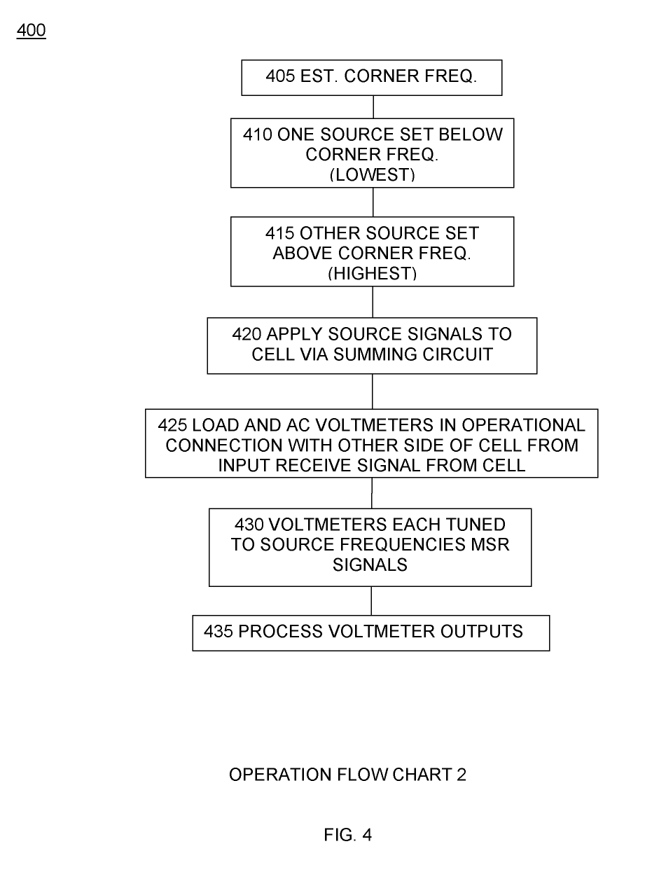

FIG. 4 is a second flow chart 400 of a method of operation of an embodiment of the invention. The frequency at which the susceptance of the sample equals its conductance is estimated (referred to as the corner frequency) 405; one sine wave source is set below the corner frequency, in the case of multiple samples the source is set below the lowest corner frequency 410; another sine wave source is set above the corner frequency, in the case of multiple samples the source is set above the highest corner frequency 415; the sine wave sources are applied to one side of the test cell via the summing circuit 420; load and AC voltmeters are operationally attached to the other side of the test cell and receive signal from cell 425; voltmeters are tuned, one to the lower frequency source, the other to the higher frequency source to measure cell signals 430; processor attached to the voltmeters measures sine wave amplitudes 435. In embodiments, the voltmeter functions can be shared. The order of steps provided may be varied in some embodiments.

For additional embodiments, the dynamic range may be extended by varying the amplitudes of the signal sources. This can be done at the source or in the summing network. In embodiments, measurement performance can be enhanced by modification of the load on the test cell including employing a transimpedance amplifier. Accuracy can be enhanced by the use of a multi-element test cell (4 wire). Embodiments use a processor and digital to analog converter (DAC) to generate sine wave signals. In other embodiments, output voltages are detected by a digital signal processor (DSP). For embodiments, the range of conductivity and dielectric of the samples to be tested is determined in advance. This can contribute to the tone selection process.

In embodiments, the load on the cell is an op-amp with a feedback network on it. One implementation is a single resistor as the feedback element. In this case, the gain of the cell plus feedback resistor is:

Gain=(feedback R)/(cell impedance) Eq. 1

The cell impedance is not a simple resistance; the gain changes with frequency. As a simplified representation, the cell appears as a capacitor in parallel with a resistor. The case of using solely a resistor for feedback provides low gain at low frequency (the conductance end of the measurement) and high gain at high frequency. This can be overcome by using a very low level tone for the high frequency. However, a low level tone impacts signal to noise. A solution includes a capacitor in parallel with the feedback resistor. This can equalize the expected gain at the high and low tone frequencies. To select its value, the highest dielectric (or relative static permittivity) anticipated is selected. ∈ᵣ is multiplied by the cell constant to get a capacitance, and the feedback is set equal to that capacitance. Similarly, the process of selecting the highest conductivity and multiplying by the cell constant generates a maximum conductivity. One over the conductivity provides the feedback resistor value.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. An apparatus for measuring conductivity and dielectric properties of a sample, said apparatus comprising:
a test cell for said sample;
at least a first sine wave signal source producing at least a first signal;
at least a second sine wave signal source producing at least a second signal;
a combiner combining said at least a first signal and said at least a second signal;
electrodes applying said at least a first signal and said at least a second signal to said test cell;
a load on an output of said test cell;
at least one measuring device, measuring output of said load; and
a processor calculating conductivity and dielectric of said sample as a function of voltages measured by said at least one measuring device.

2. The apparatus of claim 1, wherein said at least one measuring device comprises at least a pair of frequency selective AC voltage measuring devices.

3. The apparatus of claim 1, wherein said at least one measuring device comprises shared frequency selective AC voltage measuring components.

4. The apparatus of claim 1, wherein said at least one measuring device comprises at least one root mean square (RMS) detector.

5. The apparatus of claim 1, wherein said at least a first signal is a fixed frequency signal and said at least a second signal is a fixed frequency signal.

6. The apparatus of claim 1, wherein said at least a first signal and said at least a second signal are continuous, thereby reducing noise through long integration times.

7. The apparatus of claim 1, wherein varying amplitude of at least one of said at least a first signal and said at least a second signal is accomplished at said combiner.

8. The apparatus of claim 1, wherein varying amplitude of at least one of said at least a first signal and said at least a second signal is accomplished at least one of said at least a first sine wave signal source and said at least a second sine wave signal source.

9. The apparatus of claim 1, wherein said test cell comprises at least a second set of connections, whereby samples having at least one of a very high dielectric or a very high conductivity are measured.

10. The apparatus of claim 1, wherein said load is an operational amplifier (op amp) acting as a transimpedance amplifier.

11. The apparatus of claim 1, wherein said load is an operational amplifier with a feedback network.

12. The apparatus of claim 11, wherein said feedback network is a feedback resistor wherein gain of said test cell plus said feedback resistor equals feedback resistance divided by impedance of said test cell.

13. The apparatus of claim 11, wherein said feedback network comprises a feedback resistor and a capacitor in parallel with said feedback resistor wherein gain at high and low signal frequencies is equalized.

14. The apparatus of claim 11, wherein feedback capacitance equals highest anticipated value of said dielectric (∈ᵣ) multiplied by cell constant of said test cell, and resistance value of said feedback resistor equals the inverse of highest anticipated value of said conductivity multiplied by cell constant of said test cell.

15. A method for measuring conductivity and dielectric properties of at least one sample, said method comprising:
estimating a corner frequency of said sample;
selecting at least a first sine wave source frequency below said corner frequency;
selecting at least a second sine wave source frequency above said corner frequency;
applying at least a first sine wave signal at said at least a first sine wave source frequency to a summer;
applying at least a second sine wave signal at said at least a second sine wave source frequency to said summer;
applying output of said summer to a test cell of said sample;
measuring output of a load of said test cell with at least one AC voltage measurement component;
tuning said at least one AC voltage measuring component to said at least a first source frequency, producing at least a first measurement;
tuning said at least one AC voltage measuring component to said at least a second source frequency, producing at least a second measurement;
processing said at least a first measurement and said at least a second measurement;
providing values of conductivity and dielectric properties of said sample from said processing.

16. The method of claim 15, wherein said step of estimating a corner frequency of said sample comprises estimating corner frequency to be where susceptance equals conductance of said sample, and wherein range of values of said conductivity and said dielectric of said sample is determined in advance.

17. The method of claim 15, wherein amplitude of at least one of said at least a first sine wave signal and said at least a second sine wave signal is varied, thereby extending dynamic range.

18. The method of claim 15, further comprising the step of adjusting value of at least one resistor of said summer to provide equal levels of signals at output of said test cell.

19. The method of claim 15, wherein said at least one sample comprises multiple samples; wherein said at least a first sign wave source frequency is below lowest corner frequency of said multiple samples and said at least a second sign wave source frequency is above highest corner frequency of said multiple samples.

20. An apparatus for measuring conductivity and dielectric properties of a sample, said apparatus comprising:
a test cell for said sample, said sample comprising at least one of oil, fuels, and gasoline/ethanol mixtures, and said test cell is a multi-element test cell comprising four wires, whereby accuracy is enhanced;
at least a first sine wave signal source producing at least a first signal;
at least a second sine wave signal source producing at least a second signal, wherein property parameter value range is established by an ability to space said at least first signal and said at least second signal far apart in frequency;
a combiner combining said at least a first signal and said at least a second signal, wherein said combiner comprises a resistive summer producing a combined signal, and wherein said combiner comprises a low pass filter whereby noise is limited;
electrodes applying said at least a first signal and said at least a second signal to said test cell;
a load on an output of said test cell, wherein said load is a resistor;
at least a pair of frequency selective AC voltage measuring devices measuring output of said load; and
a processor calculating values of said conductivity and said dielectric properties of said sample as a function of voltages measured by said at least a pair of frequency selective AC voltage measuring devices, whereby simultaneous readings of said conductivity and said dielectric properties are accurately calculated rather than estimated.
